(19) United States
(12) Patent Application Publication
(10) Pub. No.: US 2021/0389347 A1
(43) Pub. Date: Dec. 16, 2021

(54) TEST PROBE

(71) Applicant: WINWAY TECHNOLOGY CO., LTD., Kaohsiung (TW)

(72) Inventor: Chyi-Lang LAI, Kaohsiung (TW)

(21) Appl. No.: 16/897,504

(22) Filed: Jun. 10, 2020

(51) Int. Cl. G01R 1/067; G01R 3/00

(52) U.S. Cl. CPC G01R 1/06738; G01R 3/00

(57) ABSTRACT

A test probe includes a main body extending along an axis, and a contact unit connected to the main body. The contact unit includes a plurality of structural components surrounding the axis and extending outwardly from the main body along the axis. Each structural component has a pointed tip suitable for contact with an object to be tested, and at least one ridgeline connected to the pointed tip. The at least one ridgeline is inclined with respect to a reference surface that passes through said pointed tip and that is perpendicular to the axis, and is configured to form an included angle with the reference surface. The included angle is smaller than 30 degrees.

### FIELD

The disclosure relates to an electrical testing component, more particularly to a test probe.

### BACKGROUND

Referring to FIG. 1, an existing test probe 2 includes a main body 21, and four contact portions 22 extending outwardly from the main body 21. Each contact portion 22 has a pyramidal shape with a pointed tip 221 opposite to the main body 21. The test probe 2 can perform an electrical test in response to different types of electrical contacts of an electronic component to be tested through equal distribution of the contact portions 22. During electrical testing, to ensure stable contact between the test probe 2 and one of the electrical contacts of the electronic component, the contact portions 22 do not only touch the corresponding electrical contact, but the pointed tips 221 thereof will penetrate the electrical contact by a tiny distance to improve the stability of the electrical testing. In order to increase the pressure per unit area so as to permit easy penetration of the pointed tips 221 of the contact portions 22, the pointed tips 221 are bound to be in sharp forms to reduce the unit area of contact, so that under the case where same external force is provided, the pressures of the pointed tips 221 penetrating into the electrical contact are increased.

Although the pointed tips 221 of the contact portions 22 have good penetration performance, their structural strengths are adversely affected. When in contact with a small area and have to bear the external force during contact, the pointed tips 221 are relatively easy to wear and passivate. Referring to FIG. 2, the pointed tips 221 frequently subjected to external forces become worn, are not pointed anymore, and cannot achieve the effect of penetration during contact. When the stability of the electrical testing cannot be maintained, the existing test probe 2 must be replaced with a new one, so that the service life thereof is short.

### SUMMARY

Therefore, an object of the present disclosure is to provide a test probe that is capable of alleviating at least one of the drawbacks of the prior art.

According to this disclosure, a test probe includes a main body extending along an axis, and a contact unit connected to the main body. The contact unit includes a plurality of structural components surrounding the axis and extending outwardly from the main body along the axis. Each structural component has a pointed tip suitable for contact with an object to be tested, and at least one ridgeline connected to the pointed tip. The at least one ridgeline is inclined with respect to a reference surface that passes through said pointed tip and that is perpendicular to the axis, and is configured to form an included angle with the reference surface. The included angle is smaller than 30 degrees.

### BRIEF DESCRIPTION OF THE DRAWINGS

Other features and advantages of the disclosure will become apparent in the following detailed description of the embodiments with reference to the accompanying drawings, of which:

FIG. 1 is a fragmentary perspective view of an existing test probe;

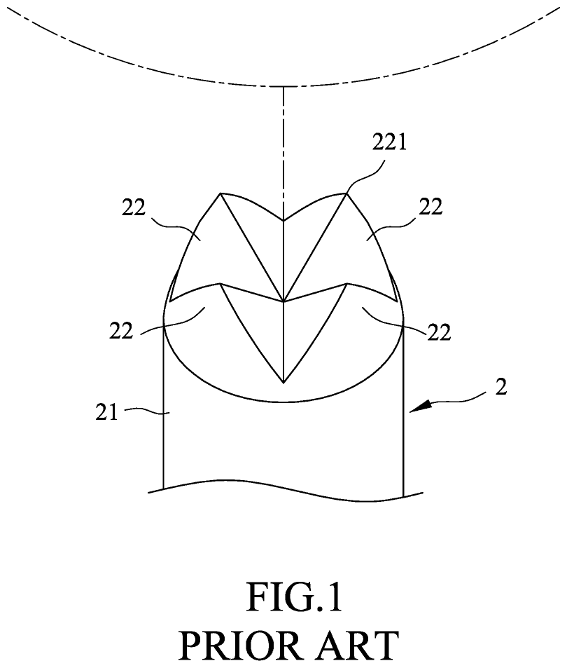

FIG. 2 is an enlarged schematic side view, illustrating the drawback of the existing test probe;

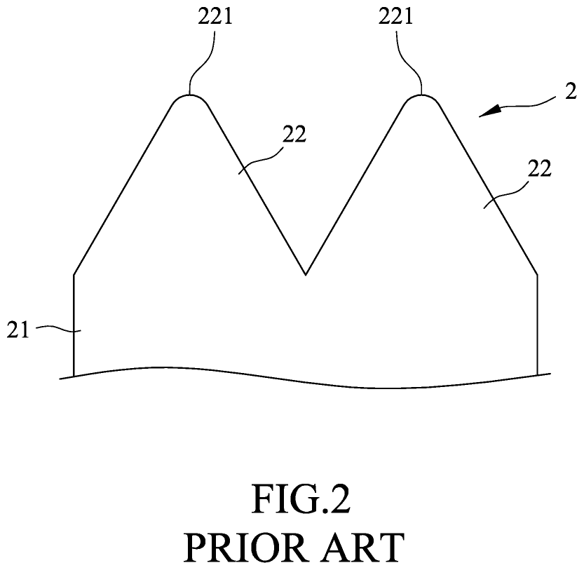

FIG. 3 is a fragmentary perspective view of a test probe according to the first embodiment of the present disclosure;

FIG. 4 is a fragmentary side view of the first embodiment;

FIG. 5 is a view similar to FIG. 4, but illustrating how the first embodiment is used in testing a ball-shaped electrical contact;

FIG. 6 is a schematic view, illustrating the effect of the first embodiment;

FIG. 7 is a fragmentary perspective view of a test probe according to the second embodiment of the present disclosure;

FIG. 8 is a fragmentary side view of the second embodiment;

FIG. 9 is a view similar to FIG. 8, but taken from another angle; and

FIG. 10 is a schematic view, illustrating the effect of the second embodiment.

### DETAILED DESCRIPTION

Before the present disclosure is described in greater detail, it should be noted herein that like elements are denoted by the same reference numerals throughout the disclosure.

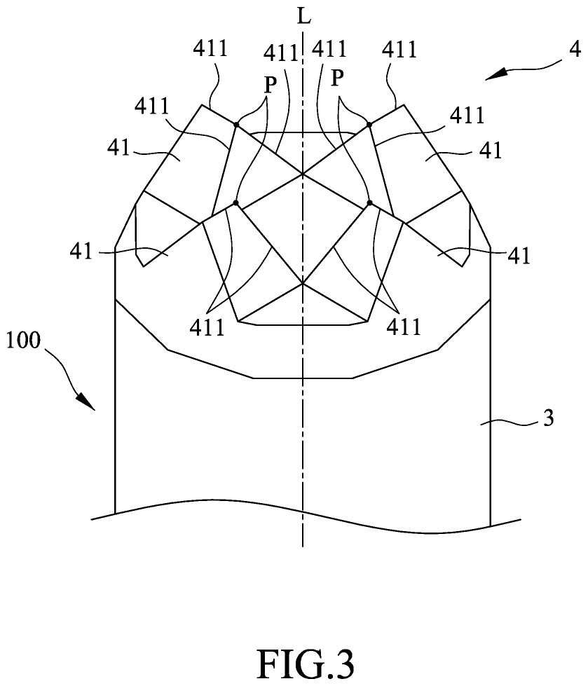

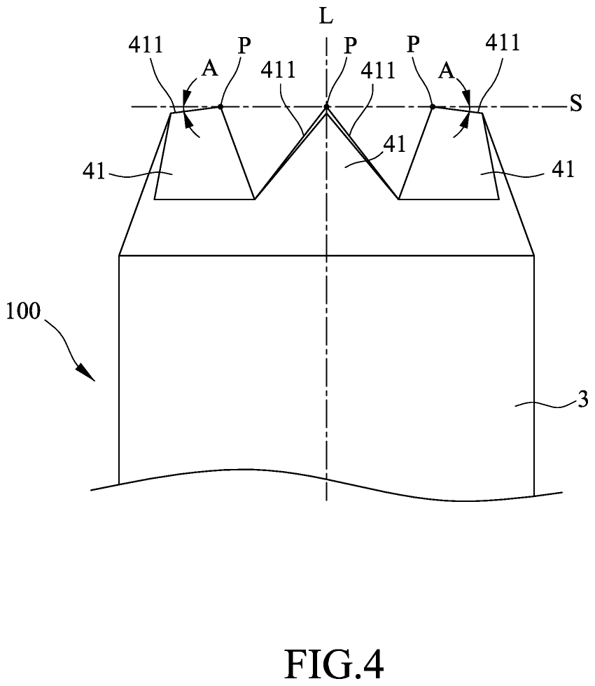

Referring to FIGS. 3 and 4, a test probe 100 according to the first embodiment of the present disclosure includes a main body 3 extending along an axis (L), and a contact unit 4 connected to the main body 3. It should be noted herein that, to perform an actual electrical test, a plurality of the test probes 100 are used that correspond to a plurality of electrical contacts of an electronic component to be tested. But, in order to clearly show the efficacy of the test probe 100 of this disclosure, only a single test probe 100 corresponding to a single electrical contact of the electronic component to be tested will be described hereinafter.

The contact unit 4 of the test probe 100 includes four structural components 41 surrounding the axis (L) and extending outwardly from the main body 3 along the axis (L). The structural components 41 are equiangularly spaced apart from each other in this embodiment. Each structural component 41 has a substantially triangular prism shape with a pointed tip (P) suitable for contact with the electrical contact of the electronic component to be tested, and three ridgelines 411 connected to the pointed tip (P) and equiangularly spaced apart from each other. One of the ridgelines 411 is inclined with respect to a reference surface (S) that passes through the pointed tip (P) and that is perpendicular to the axis (L), and forms an included angle (A) with the reference surface (S). The included angle (A) is smaller than 30 degrees. In this embodiment, the included angle (A) is 5-15 degrees, preferably, 10 degrees. Through this, the structural components 41 are substantially symmetrical with the axis (L) as the reference, and the stability during contact is optimized.

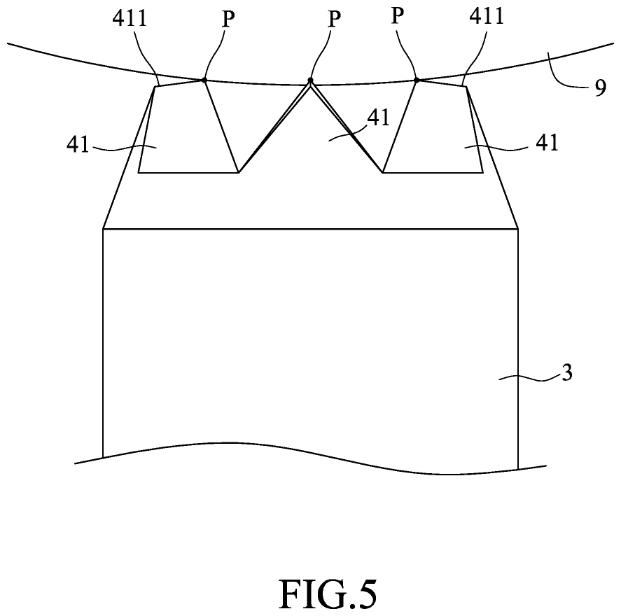

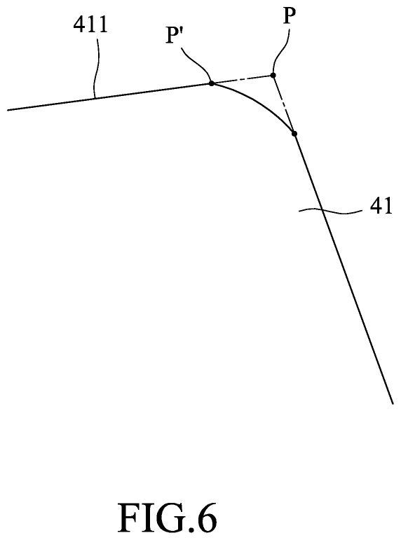

Referring to FIG. 5, in combination with FIG. 4, taking for example the first embodiment is used for contacting a ball-shaped electrical contact 9, with the pointed tips (P) of the four equally spaced apart structural components 41 simultaneously abutting against the ball-shaped electrical contact 9 (only three pointed tips (P) are visible in FIG. 5), the structural components 4 can indeed contact and form a stable electrical connection with the ball-shaped electrical contact 9. Next, referring to FIG. 6, in combination with FIG. 5, the pointed tip (P) of any one of the structural components 41 is inevitable to wear and lose the sharpness under long term use; however, other pointed tips (P′) (only one is marked in FIG. 6) with specific patterns similar to the original pointed tip (P) will be formed on the three ridgelines 411 around the worn pointed tip (P). Apart from being able to achieve stable electrical connection with the ball-shaped electrical contact 9, the first embodiment can also prolong the service life thereof through the re-forming of the pointed tips (P′) when the original pointed tip (P) is worn due to the long term use.

It is worth to mention herein that although four structural components 41 are exemplified in this embodiment, in actual practice, the number of the structural components 41 may vary, and may be three, five or any other number, as long they can be equally spaced apart from each other. Further, with each structural component 41 having at least one ridgeline 411 that forms an included angle (A) of a specific value with the reference surface (S), the service life thereof can be prolonged.

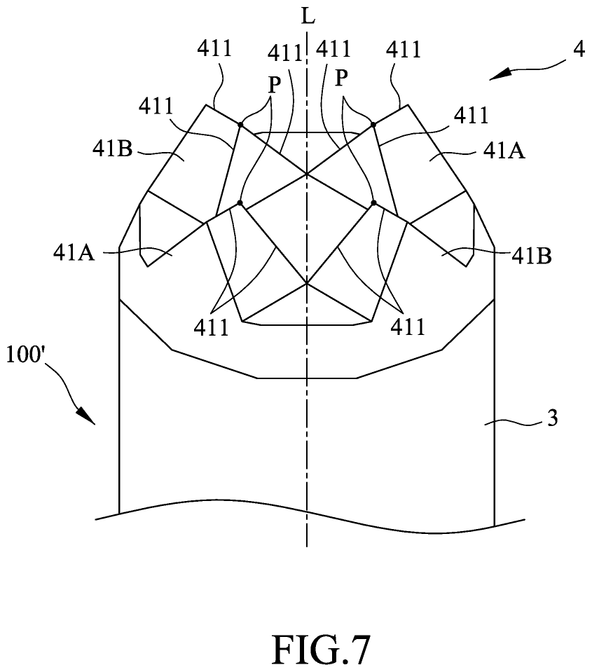

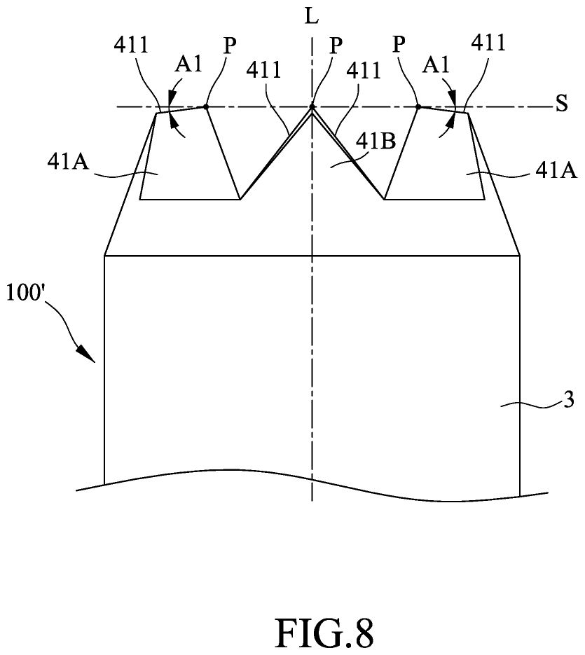

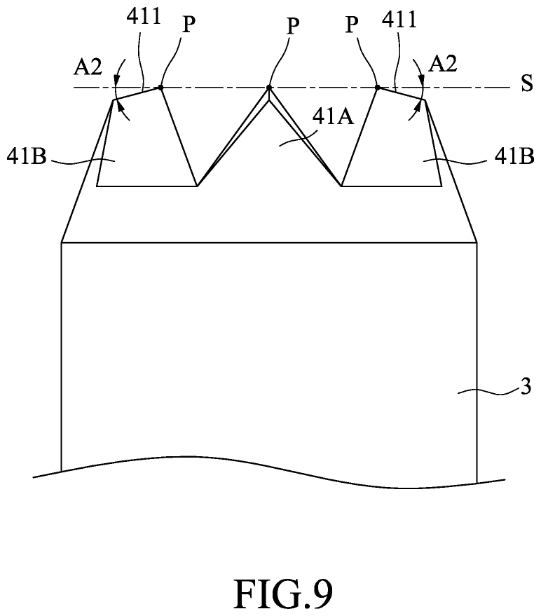

Referring to FIGS. 7 to 9, the second embodiment of the test probe 100′ of this disclosure is shown to be identical to the first embodiment. However, in the second embodiment, the four structural components (41A, 41B) of the contact unit 4 are arranged in pairs, and are symmetrical about the axis (L). The included angle (A1) of each of the pair of structural components (41A) has a value different from the included angle (A2) of each of the other pair of structural components (41B), as shown in FIGS. 8 and 9. That is, there are two different included angles (A1, A2) in this embodiment.

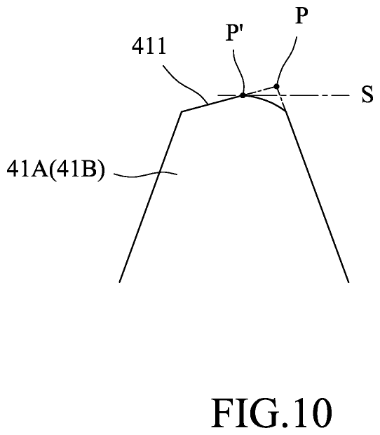

The difference between FIGS. 8 and 9 is that each of FIGS. 8 and 9 is obtained by rotating the main body 3 of the test probe 100′ by 90 degrees with the axis (L) serving as the axis of rotation. Initially, the pointed tips (P) of the two pairs of the structural components (41A, 41B) are simultaneously in contact with the electrical contact of the electronic component to be tested (not shown), because the included angle (A1) and the included angle (A2) are different, the pointed tips (P) of the two pairs of the structural components (41A, 41B) will bear different forces, so that the degree of wear of the pointed tips (P) thereof will also differ. Under the long term use, as shown in FIG. 10, the pointed tip (P) will wear, and another pointed tip (P′) will be formed on the ridgeline 411 just like the first embodiment, thereby achieving the effect of stable contact with the electrical contact of the electronic component to be tested. Moreover, since the degree of wear of the pointed tips (P) of the pair of structural components (41A) is different from the degree of wear of the pointed tips (P) of the pair of structural components (41B) and at different speeds, the structural components (41A, 41B) will alternately bear relatively large contact forces one after the other. Therefore, the service life of the second embodiment can be prolonged through the dispersing wearing rate of the structural components (41A, 41B).

Similarly, in actual practice, the second embodiment may use six, eight or other numbers of the structural components (41A, 41B) as long as they can permit arrangement of the structural components (41A, 41B) in pairs. Another alternative is, the structural components (41A, 41B) may not be arranged in pairs, but in groups, as long as the structural components (41A, 41B) of each group have different included angles (A), so that the pointed tips (P) of the structural components (41A, 41B) of each group can have a degree of wear different from that of the other groups, thereby achieving the effect of prolonging the service life of the present disclosure.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A test probe comprising:
a main body extending along an axis; and
a contact unit connected to said main body and including a plurality of structural components surrounding the axis and extending outwardly from said main body along the axis, each of said structural components having a pointed tip suitable for contact with an object to be tested, and at least one ridgeline connected to said pointed tip, said at least one ridgeline being inclined with respect to a reference surface that passes through said pointed tip and that is perpendicular to the axis, and being configured to form an included angle with the reference surface, said included angle being smaller than 30 degrees.

2. The test probe as claimed in claim 1, wherein said structural components are equiangularly spaced apart from each other.

3. The test probe as claimed in claim 1, wherein said structural components are arranged in pairs and are symmetrical about the axis.

4. The test probe as claimed in claim 3, wherein said included angles of said structural components of each pair are the same.

5. The test probe as claimed in claim 3, wherein said included angles of said structural components of one of said pairs of structural components have a value different from that of said included angles of said structural components of the other one of said pairs of structural components.

6. The test probe as claimed in claim 1, wherein said included angle is 5-15 degrees.

7. The test probe as claimed in claim 1, wherein each of said structural components has a substantially triangular prism shape.
